(19) United States
(12) Patent Application Publication
(10) Pub. No.: US 2025/0216799 A1
(43) Pub. Date: Jul. 3, 2025

(54) RETICLE STAGE

(71) Applicant: SAMSUNG ELECTRONICS CO., LTD., Suwon-si (KR)

(72) Inventors: Seonghyeon KIM, Suwon-si (KR); Dongjin LEE, Suwon-si (KR); Yozo MATSUDA, Suwon-si (KR); Sunmoon KIM, Suwon-si (KR); Jeonggil KIM, Suwon-si (KR)

(73) Assignee: SAMSUNG ELECTRONICS CO., LTD., Suwon-si (KR)

(21) Appl. No.: 18/903,621

(22) Filed: Oct. 1, 2024

(30) Foreign Application Priority Data
Jan. 3, 2024 (KR) 10-2024-0000728

(51) Int. Cl. G03F 7/00

(52) U.S. Cl. CPC G03F 7/70716; G03F 7/70708

(57) ABSTRACT

Provided is a reticle stage including a main base, an electrostatic chuck connected to the main base, a first surface of the electrostatic chuck being configured to support a reticle, a safety bar rotatably on the main base or electrostatic chuck, and a support member on the safety bar, an end of the support member overlapping with an edge of the reticle in a vertical direction, wherein the support member includes a plate portion on a first surface of the safety bar, and a support portion extending from the plate portion and configured to surface contact the reticle based on the reticle falling from the electrostatic chuck.

### CROSS-REFERENCE TO RELATED APPLICATION

This application claims priority to Korean Patent Application No. 10-2024-0000728 filed on Jan. 3, 2024 in the Korean Intellectual Property Office, the disclosure of which is incorporated herein by reference in its entirety.

### BACKGROUND

Embodiments of the present disclosure relate to a reticle stage.

When an emergency situation occurs within an extreme ultraviolet (EUV) facility, a reticle may fall from an electrostatic chuck of a reticle stage. In this case, safety catches are installed on the reticle stage to prevent the reticle from falling into a scanner.

In addition, four safety catches are generally provided on the reticle stage and may catch the edges of the reticle that may fall from the electrostatic chuck, thereby preventing the reticle from falling into the scanner.

However, since the safety catches may have an “L” shape, which is a simple structure that may hold the reticle with a bent portion, when the reticle that is falling is seated at the end of the safety catches, the reticle may be damaged.

### SUMMARY

One or more embodiments provide a reticle stage capable of preventing damage to a reticle when the reticle falls.

According to an aspect of one or more embodiments, there is provided a reticle stage including a main base, an electrostatic chuck connected to the main base, a first surface of the electrostatic chuck being configured to support a reticle, a safety bar rotatably on the main base or electrostatic chuck, and a support member on the safety bar, an end of the support member overlapping with an edge of the reticle in a vertical direction, wherein the support member includes a plate portion on a first surface of the safety bar, and a support portion extending from the plate portion and configured to surface contact the reticle based on the reticle falling from the electrostatic chuck.

According to another aspect of one or more embodiments, there is provided a reticle stage including a main base in an internal space of a chamber, an electrostatic chuck connected to the main base and a first surface of the electrostatic chuck being configured to detachably support a reticle, a safety bar rotatably on the main base or the electrostatic chuck, and a support member on the safety bar, an end of the support member overlapping with an edge of the reticle in a vertical direction, wherein the support member includes a plate portion on a bottom surface of the safety bar, and a support portion extending from the plate portion and having a curved surface convex toward the electrostatic chuck.

According to still another aspect of one or more embodiments, there is provided an extreme ultraviolet exposure apparatus including a light source configured to emit light, an optical system configured to control the emitted light, the optical system including a main base, an electrostatic chuck connected to the main base, a first surface of the electrostatic chuck being configured to detachably support a reticle, a safety bar rotatably on the main base or electrostatic chuck, and a support member on the safety bar, an end of the support member overlapping with an edge of the reticle in a vertical direction, the support member including a plate portion on a first surface of the safety bar, and a support portion extending from the plate portion and configured to surface contact the reticle based on the reticle falling from the electrostatic chuck, and a wafer stage.

### BRIEF DESCRIPTION OF DRAWINGS

The above and other aspects, features, and advantages of one or more embodiments will be more clearly understood from the following detailed description, taken in conjunction with the accompanying drawings, in which:

FIG. 1 is a schematic configuration diagram illustrating an extreme ultraviolet exposure apparatus in which a reticle stage is installed according to one or more embodiments;

FIG. 2 is a configuration diagram illustrating a reticle stage according to one or more embodiments;

FIG. 3 is an enlarged view of portion A of FIG. 2;

FIG. 4 is a bottom view of portion A of FIG. 2;

FIG. 5 is a diagram illustrating an operation of a reticle stage according to one or more embodiments; and

FIG. 6 is an enlarged view illustrating a region corresponding to portion A of FIG. 2 of the reticle stage according to one or more embodiments.

### DETAILED DESCRIPTION

Hereinafter, embodiments will be described with reference to the accompanying drawings. Embodiments described herein are example embodiments, and thus, the disclosure is not limited thereto.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

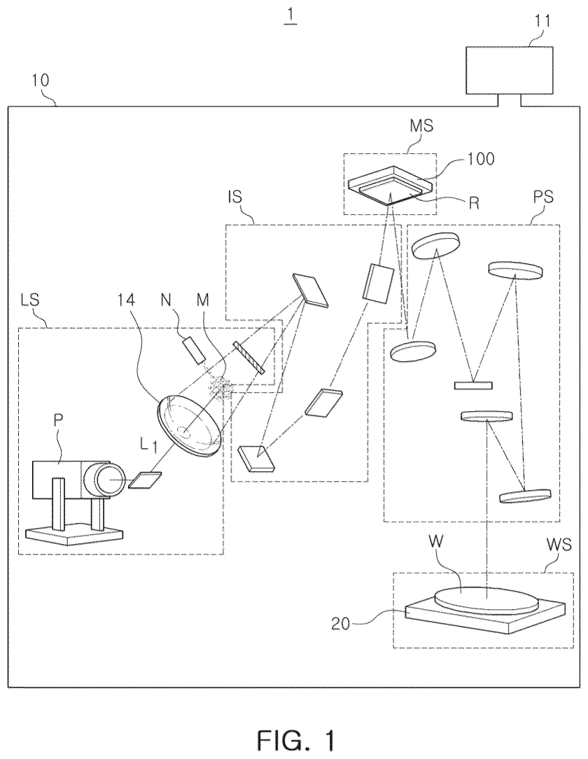

FIG. 1 is a schematic configuration diagram illustrating an extreme ultraviolet exposure apparatus in which a reticle stage is installed according to one or more embodiments.

Referring to FIG. 1, an extreme ultraviolet exposure apparatus 1 includes a light source system LS generating exposure light, an optical system controlling and patterning the exposure light generated by the light source system LS, and a substrate system WS.

The optical system includes an illuminating optical system IS transferring the exposure light generated by the light source system LS, a mask system MS patterning the exposure light transferred from the illustrating optical system, and a projecting optical system PS transferring patterned light from the mask system MS onto the substrate system WS.

The light source system LS, illustrating optical system IS, mask system MS, projecting optical system PS, and substrate system WS are accommodated in a chamber 10 isolating these elements from the outside. A vacuum pump may be connected to the chamber 10, and a molecular oxygen supply device 11 may be connected to the chamber 10.

In addition, the light source system LS may generate extreme ultraviolet exposure light by focusing and reflecting a high-temperature plasma beam, generated by emitting a laser light L₁ having a high-intensity pulse to be transmitted through to a collector optical member 14 and toward a target material M sprayed from a source nozzle unit N.

A reticle stage 100 may be provided in the mask system MS. In addition, the substrate system WS may be provided with a wafer stage 20 on which a wafer W is mounted.

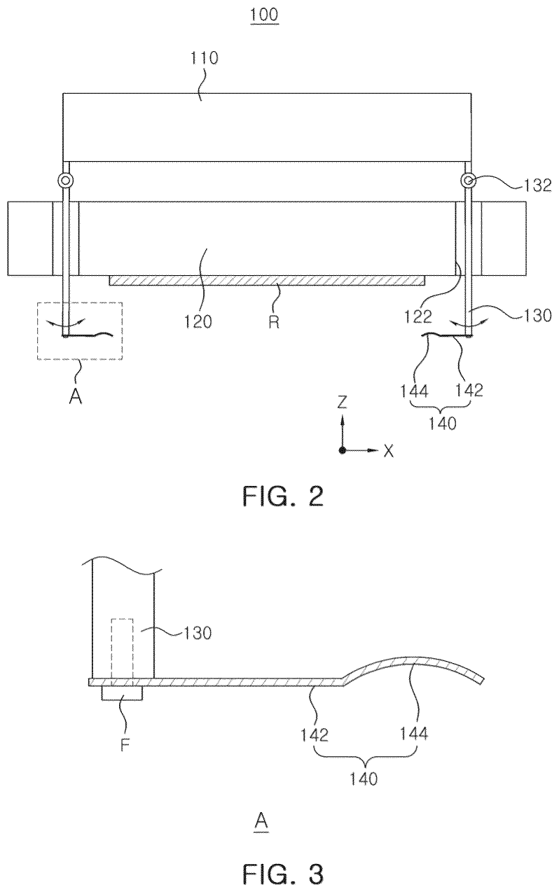

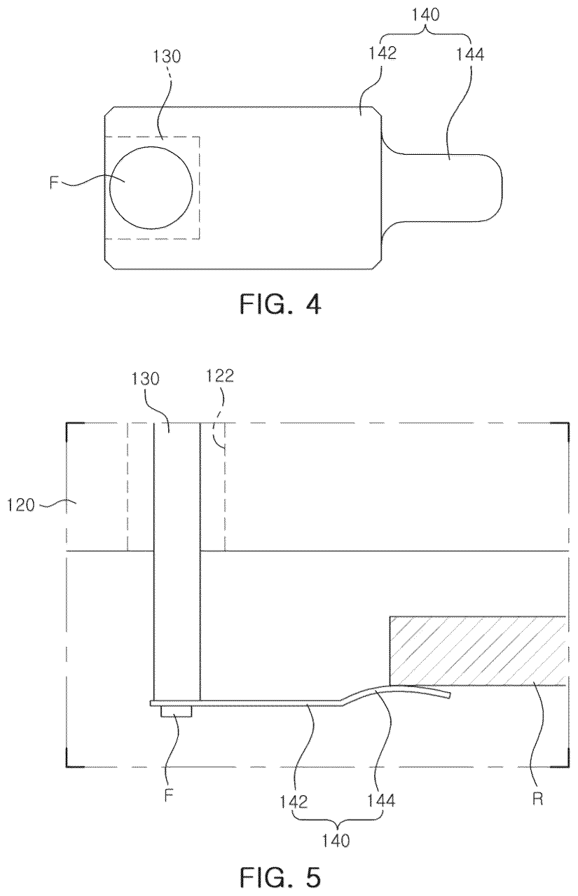

FIG. 2 is a configuration diagram illustrating a reticle stage according to one or more embodiments, FIG. 3 is an enlarged view of region A of FIG. 2, and FIG. 4 is a bottom view of the region A of FIG. 2.

Referring to FIGS. 2 to 4, the reticle stage 100 according to one or more embodiments includes a main base 110, an electrostatic chuck 120, a safety bar 130, and a support member 140.

The electrostatic chuck 120 may be connected to the main base 110. As an example, the safety bar 130 may be rotatably installed on and connected to the main base 110 by the medium of a hinge 132. For example, the hinge 132 may be provided between the safety bar 130 and the main base 110. In addition, the main base 110 may be provided with a driving unit to rotate the safety bar 130. As an example, the driving unit may include a coil and a magnet for rotating the safety bar 130 by electromagnetic force. However, embodiments are not limited thereto, and the driving unit may be an actuator rotating the safety bar 130 by hydraulic pressure or the like.

The electrostatic chuck 120 may be connected to the main base 110. As an example, a power source may be connected to the electrostatic chuck 120, and when power is supplied to the electrostatic chuck 120, a charge (for example, a positive charge) may be formed on a lower surface of the electrostatic chuck 120. In addition, a charge (e.g., a negative charge) may be formed on an upper surface of the reticle R. Accordingly, electrostatic force is generated between the electrostatic chuck 120 and the reticle R. Thus, the reticle R may be attached to the electrostatic chuck 120, and, for example, a lithography process may be performed thereafter. The electrostatic chuck 120 may be provided with an installation hole 122 through which the safety bar 130 passes.

The safety bar 130 may be disposed to pass through the installation hole 122 provided in the electrostatic chuck 120. As an example, the safety bar 130 may rotate with respect to the hinge 132. For example, four safety bars 130 may be arranged on the electrostatic chuck 120 to be spaced apart from each other. However, the number of safety bars 130 may be variably changed. According to one or more embodiments, the safety bar 130 may be rotatably installed on the main base 110 by the hinge 132. However, embodiments are not limited thereto, and a pair of safety bars 130 facing each other may be installed to be spaced apart from each other or relatively close to each other in the main base 110 or the electrostatic chuck 120.

The support member 140 may be installed on the safety bar 130. As an example, the support member 140 may be installed to be fixed through a fixing member F on a bottom surface of the support member 140. The support member 140 may include a plate portion 142 installed on the safety bar 130 and a support portion 144 extending from the plate portion 142 and supporting the reticle R falling from the electrostatic chuck 120. As an example, the support portion 144 may have a curved surface that is upwardly convex toward the electrostatic chuck 120. When the reticle R is initially being attached to the electrostatic chuck 120, the safety bar 130 may rotate so that the support member 140 is disposed outside of the reticle R to prevent interference between the support member 140 and the reticle R. For example, when the reticle R is attached to the electrostatic chuck 120, the support member 140 and the reticle R may not overlap in a vertical direction (Z direction). In addition, when the reticle R remains attached to the electrostatic chuck 120, the safety bar 130 is rotated so that the support member 140 is disposed below the edge of the reticle R such that the edge of the reticle R overlaps with the support member 140 in the vertical direction. Accordingly, when the reticle R falls from the electrostatic chuck 120 in an emergency situation, such as a power outage, the reticle R may be seated on the support portion 144 of the support member 140. At this time, the support portion 144 having a curved surface may be deformed, thereby suppressing damage to the reticle R. In addition, the support member 140 may be formed of an elastic material. As an example, the support member 140 may be formed of a material that may withstand and not be deformed in a hydrogen atmosphere, EUV environment, etc. For example, the support member 140 may be formed of stainless steel. As an example, a thickness of the support member 140 may range from 0.3 mm to 0.8 mm in the vertical direction. When the thickness of the support member 140 is less than 0.3 mm, the support member 140 may be plastic-deformed due to increasing stress applied to the support member 140 when supporting the falling reticle R. In addition, when the thickness of the support member 140 exceeds 0.8 mm, the amount of impact applied to the reticle R may increase when the support member 140 supports the falling reticle R.

A width of the plate portion 142 may be greater than a width of the support portion 144 in a horizontal direction (X direction). In addition, the support portion 144 may be formed to have a rounded portion connected to the plate portion 142. In addition, the end of the support portion 144 may also be formed to be rounded.

Here, a mechanism for suppressing damage to the reticle R by the support member 140 when the reticle R falls from the electrostatic chuck 120 is briefly described. When the reticle R falls to be dropped on the support member 140, force (the amount of impact) applied at the time of impact should be reduced in order to reduce damage to the reticle R. The applied force is inversely proportional to a collision time, and as the collision time increases, the applied force may decrease. In addition, damage to the reticle R occurs due to force applied per unit area, and thus, in order to more effectively distribute the applied force, the reticle R may need to contact the largest area as possible at the time of impact.

By changing the thickness of the support member 140, the amount of deformation of the support member 140 may increase, thereby reducing the collision time. Also, as described above, the amount of impact applied to the reticle R may be reduced as stress experienced by the reticle R has a cubic plane curve only within a limited thickness range of the support member 140, for example, only within the range of 0.3 mm to 0.8 mm.

In addition, in order to more effectively distribute the stress applied to the reticle R, the reticle R needs to be in surface contact with the support portion 144 of the support member 140 as shown in FIG. 5. In addition, compared to a case in which the reticle R is in line contact with the support portion 144 of the support member 140, when the reticle R is in surface contact with the support portion 144 of the support member 140, the amount of impact received by the reticle R may be reduced by approximately 35%.

As described above, by providing the support member 144 having a curved surface in the support member 140, when the reticle R falls from the electrostatic chuck 120 and is seated on the support member 140, damage to the reticle R may be suppressed.

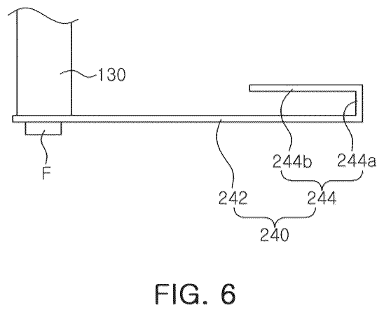

FIG. 6 is an enlarged view illustrating a region corresponding to the region A of FIG. 2 of the reticle stage according to one or more other embodiments.

Referring to FIG. 6, a support member 240 may be installed on the safety bar 130. As an example, the support member 240 may be installed to be fixed through the fixing member F on a bottom surface of the support member 240. The support member 240 may include a plate portion 242 installed on the safety bar 130 and a support portion 244 extending from the plate portion 242 and supporting the reticle R falling from the electrostatic chuck 120. As an example, the support portion 244 may include a first support portion 244a extending vertically from the plate portion and a second support portion 244b extending from the first support portion 244a horizontally and parallel to the plate portion 242. As shown in FIG. 2, the safety bar 130 is rotated so that the support member 240 is disposed outside the reticle R to prevent interference between the support member 240 and the reticle R when the reticle R is attached to the electrostatic chuck 120 (see FIG. 2). In addition, when the reticle R remains attached to the electrostatic chuck 120, the safety bar 130 is rotated so that the support member 240 is disposed below the edge of the reticle R. Accordingly, when the reticle R falls from the electrostatic chuck 120 in an emergency, such as a power outage, the reticle R may be seated on the support portion 244 of the support member 240. At this time, the support portion 244 including the first and second support portions 244a and 244b may be deformed, thereby suppressing damage to the reticle R. In addition, the support member 240 may be formed of an elastic material. As an example, the support member 240 may be formed of a material that may withstand a hydrogen atmosphere, EUV environment, etc. For example, the support member 240 may be formed of stainless steel. As an example, a thickness of the support member 240 may range from 0.3 mm to 0.8 mm. When the thickness of the support member 240 is less than 0.3 mm, the support member 240 may be plastic-deformed due to increasing stress applied to the support member 240 when supporting the falling reticle R. In addition, when the thickness of the support member 240 exceeds 0.8 mm, the amount of impact applied to the reticle R may increase when the support member 240 supports the falling reticle R.

As described above, since the support member 240 includes the support portion 244 having the first and second support portions 244a and 244b, damage to the reticle R when the reticle R falls from the electrostatic chuck 120 and is seated on the support member 240 may be suppressed.

According to embodiments, the reticle stage capable of suppressing damage to the reticle when the reticle falls may be provided.

While embodiments have been shown and described above, it will be apparent to those skilled in the art that modifications and variations could be made without departing from the scope as defined by the appended claims and their equivalents.

What is claimed is:

1. A reticle stage comprising:
a main base;
an electrostatic chuck connected to the main base, a first surface of the electrostatic chuck being configured to support a reticle;
a safety bar rotatably on the main base or electrostatic chuck; and
a support member on the safety bar, an end of the support member overlapping with an edge of the reticle in a vertical direction,
wherein the support member comprises:
a plate portion on a first surface of the safety bar; and
a support portion extending from the plate portion and configured to surface contact the reticle based on the reticle falling from the electrostatic chuck.

2. The reticle stage of claim 1, wherein the support portion has a curved surface.

3. The reticle stage of claim 2, wherein the support portion is convex toward the electrostatic chuck.

4. The reticle stage of claim 1, wherein a thickness of the support member in the vertical direction ranges from 0.3 mm to 0.8 mm.

5. The reticle stage of claim 1, wherein, based on the reticle being adsorbed to the first surface of the electrostatic chuck, the support portion does not overlap with the reticle in the vertical direction, and based on the reticle remaining adsorbed to the first surface of the electrostatic chuck, the support portion overlaps with the reticle in the vertical direction.

6. The reticle stage of claim 5, wherein a hinge is between the safety bar and the main base, the hinge being configured to rotate the safety bar.

7. The reticle stage of claim 1, wherein a width of the plate portion is greater than a width of the support portion in a horizontal direction.

8. The reticle stage of claim 1, wherein the support member is formed of a material having elasticity withstanding a hydrogen atmosphere and extreme ultraviolet (EUV) environment.

9. The reticle stage of claim 1, wherein the support portion comprises a first support portion extending in the vertical direction from the plate portion and a second support portion extending from the first support portion in a horizontal direction parallel to the plate portion.

10. The reticle stage of claim 3, wherein a portion of the support portion connected to the plate portion is rounded.

11. The reticle stage of claim 10, wherein the end of the support portion is rounded.

12. A reticle stage comprising:
a main base in an internal space of a chamber;
an electrostatic chuck connected to the main base, a first surface of the electrostatic chuck being configured to detachably support a reticle;
a safety bar rotatably on the main base or the electrostatic chuck; and
a support member on the safety bar, an end of the support member overlapping with an edge of the reticle in a vertical direction,
wherein the support member comprises:
a plate portion on a bottom surface of the safety bar; and
a support portion extending from the plate portion and having a curved surface convex toward the electrostatic chuck.

13. The reticle stage of claim 12, wherein a thickness of the support member in the vertical direction ranges from 0.3 mm to 0.8 mm.

14. The reticle stage of claim 12, wherein a width of the plate portion is greater than a width of the support portion in a horizontal direction.

15. The reticle stage of claim 12, wherein the support member comprises a material having elasticity withstanding a hydrogen atmosphere and extreme ultraviolet (EUV) environment.

16. The reticle stage of claim 12, wherein the support portion is formed to be rounded in a portion connected to the plate portion.

17. An extreme ultraviolet exposure apparatus comprising:
a light source configured to emit light;
an optical system configured to control the emitted light, the optical system comprising:
a main base;
an electrostatic chuck connected to the main base, a first surface of the electrostatic chuck being configured to detachably support a reticle;
a safety bar rotatably on the main base or electrostatic chuck; and
a support member on the safety bar, an end of the support member overlapping with an edge of the reticle in a vertical direction, the support member comprising:
a plate portion on a first surface of the safety bar; and
a support portion extending from the plate portion and configured to surface contact the reticle based on the reticle falling from the electrostatic chuck; and
a wafer stage.

18. The extreme ultraviolet exposure apparatus of claim 17, wherein the support portion has a curved surface.

19. The extreme ultraviolet exposure apparatus of claim 18, wherein the support portion is convex toward the electrostatic chuck.

20. The extreme ultraviolet exposure apparatus of claim 17, wherein a thickness of the support member in the vertical direction ranges from 0.3 mm to 0.8 mm.
